(19) United States
(12) Patent Application Publication
(10) Pub. No.: US 2010/0052157 A1
(43) Pub. Date: Mar. 4, 2010

(54) CHANNEL FOR A SEMICONDUCTOR DIE AND METHODS OF FORMATION

(75) Inventor: David S. Pratt, Meridian, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc., Boise, ID (US)

(21) Appl. No.: 12/201,498

(22) Filed: Aug. 29, 2008

(51) Int. Cl. H01L 23/34; B29C 35/00; H01L 23/52; H01L 21/00

(52) U.S. Cl. 257/712; 425/547; 257/774; 438/109; 438/113; 257/E23.141; 257/E21.001; 257/E23.08

(57) ABSTRACT

In semiconductor die packaging, stereo lithography cures a material around the die such that a channel is defined in the material. The channel exposes a portion of the die surface, and the channel is closed off above the die surface. The same stereo lithography process may also be used to define an opening that exposes a through-silicon via extending from the die surface. An additional or alternative channel may be similarly defined at a side perpendicular to that surface. The die may be stacked with other die, and the stereo lithography process may occur before or after stacking. A heat sink contacting the channel may also be added.

### TECHNICAL FIELD

Embodiments of the invention relate generally to stereo lithography applications and the resulting devices. More specifically, embodiments of the invention relate to a cooling channel for a die, wherein the channel is defined in-part by a material having undergone a stereo lithography process.

### BACKGROUND

Stereo lithography, also known as “stereo lithography epitaxy” is a type of layered manufacturing wherein an object is conceptually divided into a series of cross-sectional layers, and the object is formed one layer at a time; with a subsequent layer being formed above and attached to the previous underlying layer.

In one type of stereo lithography, a layer of liquid curable material is located over a support structure. For instance, a platform may be lowered to a particular depth into a tank of Accura™ SI40 SL material (manufactured by 3D Systems, Inc.). Amethyst SL photoreactive epoxy resin, also from 3D Systems, is another material that may be used. A laser beam is then trained on regions of the layer associated with the relevant cross-section. Once the relevant portions of the material are at least partially cured/developed/solidified by the laser, more curable material may be added above (such as by further lowering the platform in the SI40 tank) and regions of the additional material are at least partially cured by the laser according to the next relevant cross-section. The laser's movement may be guided by a computer, Computer Assisted Drawing (CAD) software, and a vision system. The acts of adding curable material and curing relevant portions may be repeated until the object's basic structure, as defined by the combined cured cross-sections, is complete. The object may then be removed from the tank, and portions of uncured material may be removed using, for example, an alcohol-based solvent. The object may then undergo additional curing, such as with a soft bake process. Additional details concerning stereo lithography may be found in patents such as U.S. Pat. Nos. 6,875,640; 6,524,346; and 6,762,502.

Initial applications of stereo lithography included forming prototypes and tooling. Subsequent applications of stereo lithography include packaging semiconductor die, such as a memory die, wherein a die may be placed on the platform in the SI40 tank, and the SI40 may be cured on and around the die. Additional details concerning stereo lithography applications to die may be found in patents such as U.S. Pat. Nos. 6,875,640; 6,762,502; 6,549,821; 6,524,346; 6,432,752; and 6,326,698; as well as U.S. Published App. 2007/0296090.

Semiconductor die may have temperature issues, as the devices on the die generate heat, and dissipating that heat may be needed to assist with reliable operation. U.S. Pat. No. 6,730,998 is directed to using stereo lithography to provide a heat sink that conducts heat (and electricity) and defines “internally confined cavities.” (See '998 at col. 6, ln. 24-25; col. 7, ln. 54-60; FIG. 1, element 24.) The '998 patent also warns of the use of conductive materials for such an application given the risk of causing electrical shorts and device failure. (Id. at col. 14, ln. 11-21.)

Accordingly, there is a continuing need in the art for techniques and components that may address die temperature issues, as well as a more general need for additional applications of stereo lithography techniques.

### BRIEF DESCRIPTION OF THE DRAWINGS

FIG. 1. is a cross-sectional view of the prior art.

FIG. 2 is a cross-sectional view of an embodiment of the invention.

FIG. 3 is a top-down view of an embodiment of the invention.

FIGS. 4-7 depict a method embodiment directed to forming a device embodiment of the invention.

FIGS. 8, 9, and 10A illustrate cross-sectional views of embodiments of the invention.

FIGS. 10B and 10C picture exploded cross-sectional perspective views of embodiments of the invention.

FIG. 11A is a cross-sectional view of an embodiment of the invention.

FIG. 11B is a perspective cross-sectional view of the embodiment pictured in FIG. 11A.

FIG. 12 is a cross-section of an embodiment of the invention.

FIG. 13 pictures an exploded cross-sectional perspective view of an embodiment of the invention.

### DETAILED DESCRIPTION OF THE EMBODIMENTS

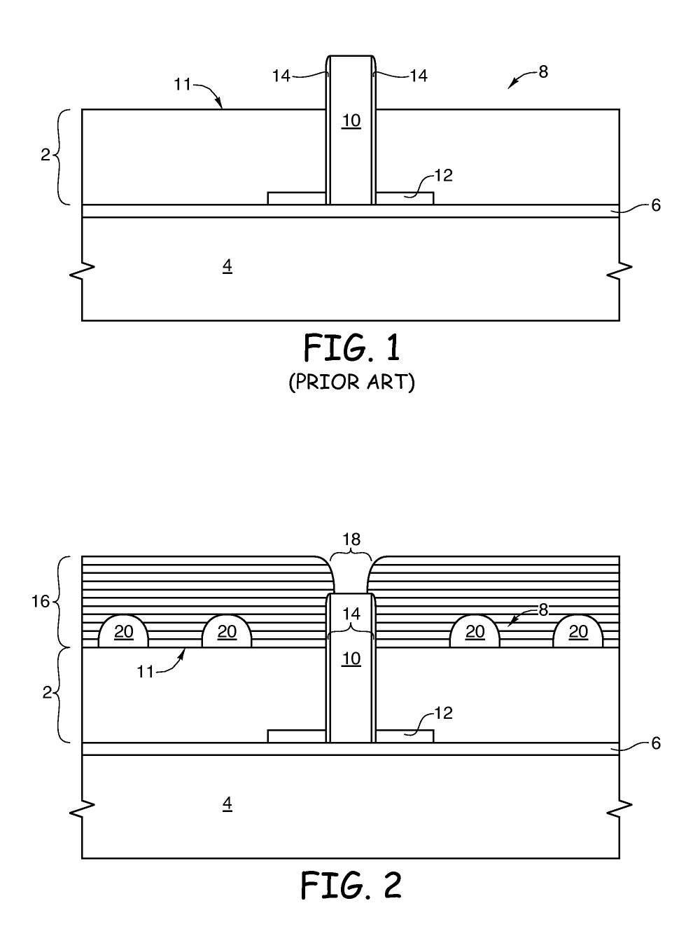

FIG. 1 illustrates a portion of a silicon wafer 2 that is attached to a carrier 4 by way of an adhesive 6. More specifically, FIG. 1 depicts a site on the wafer 2 including a die 8, which in turn includes a through-silicon via (TSV) 10. The TSV 10 comprises an electrically conductive material such as copper. Such a conductor may also be referred to in the art as a “through silicon interconnect,” or a “through wafer interconnect” (assuming the interconnect was formed on a wafer-scale workpiece). The TSV's side may be protected by passivation 14, which may be tetraethylorthosilicate (TEOS) glass, a pulsed deposition layer (PDL), or a material resulting from a CCV spin-on dielectric. The TSV 10 extends from one side 11 of the wafer 2 to a contact pad 12 at the opposing side. The pad 12 extends to die circuitry (not shown). The wafer 2 has been recessed at side 11 to effect an extension of the TSV 10 end from the die 8. Recessing may be accomplished using a silicon relief etch, for example. Such an etch may comprise a dry etch using SF₆ for a time that may depend upon the tool. For example, the STS Pegasus tool may recess side 11 sufficiently with a 30-60 second etch. Alternatively, a wet etch using tetramethylammoniumhydroxide (TMAH) may be used. Often in the art, a continuous passivation layer is added over side 11 after recessing it, and the passivation layer is partially etched to expose the TSV 10.

However, FIG. 2 illustrates an embodiment of the invention that provides an alternative to known passivation techniques. FIG. 2 depicts the portion of silicon wafer 2 as described above with passivation 16 added to side 11 using a stereo lithography process. In this embodiment, at least one layer of SI40 is added above side 11 and, after patterned laser curing and removing uncured portions, defines not only an opening 18 for the TSV 10 but also partially defines at least one channel 20. Side 11 also partially defines channel 20. As a result, channel 20 may address cooling the die 8. In some embodiments, passivation 16 may be around 5-10 microns thick. In other embodiments, passivation 16 may be around 50 microns thick. As for the channel 20, it may extend as much as around 5-10 microns from side 11. In other embodiments, the channel 20 may extend as much as around 50 microns from side 11. It is preferred but not required that channel 20 avoid intersection with a TSV 10 or other electrical conductor in order to avoid shorting concerns. In the illustrated embodiment, the shape of the channel 20, the materials, and the process are chosen such that structures need not be formed by stereo lithography to support overhanging cured portions defining the channel 20, then subsequently removed. Such supporting structures may be added in other embodiments.

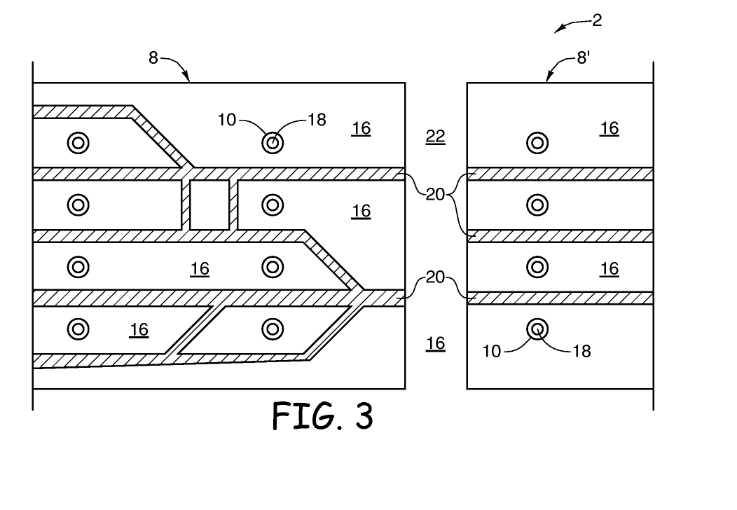

FIG. 3 illustrates a top-down cross-sectional view of an embodiment of the invention wherein two die 8 and 8′ are still part of a wafer 2. Passivation 16 is over both die 8 and 8′ and over the street 22 around them. Passivation 16 also defines channels 20. In this embodiment a channel 20 may branch, as seen over die 8, and one branch of channel 20 may intersect another channel 20 orthogonally or non-orthogonally. Further, a non-orthogonal intersection of channel 20 may be of greater assistance in terms of fluid flow (and therefore cooling) than an orthogonal intersection. Moreover, the diameter and general shape of channel 20 may be different at different points. The channels 20 extend to the edge of the die 8 and 8′. As a result, once the die 8 and 8′ are singulated, such as by sawing through the streets 22, the ends of channels 20 are opened. It is also noted in this embodiment that the channels do not extend above the street 22. Although embodiments of the invention include those wherein a channel 20 may extend from one die 8, across the street 22, to the adjacent die 8′, embodiments that do not extend channel 20 across the street 22 may allow for easier curing as well as easier rinsing of SI40 from the channel 20.

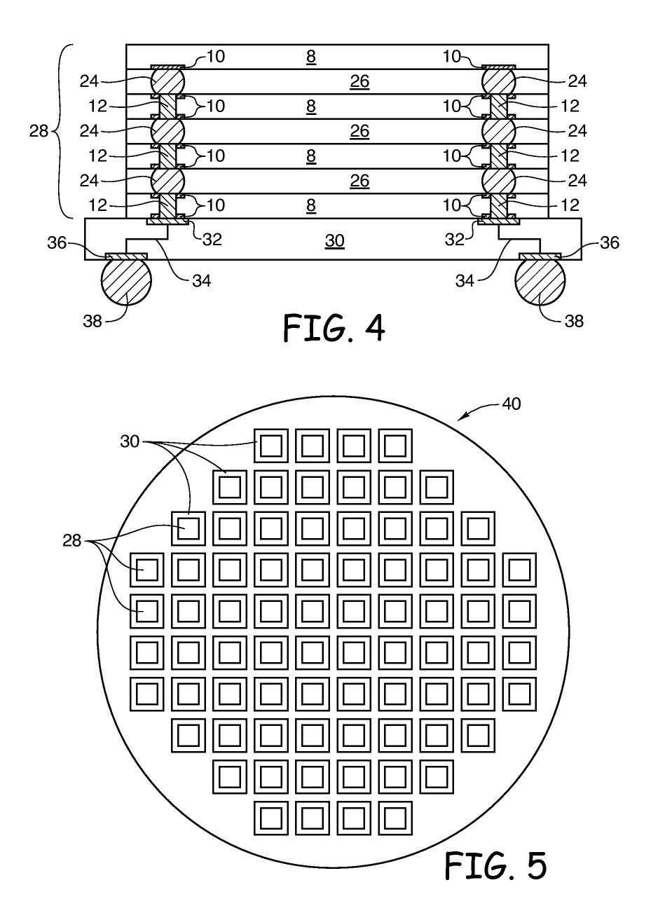

FIG. 4 serves as the starting point for describing another embodiment of the invention concerning at least one stack 28 of die 8. In stack 28, solder balls 24 connect TSV's 10 of adjacent die 8, and an underfill material 26 that has undergone a reflow process may also be located between adjacent die 8. The die stack 28 may be formed while the die 8 at one or more of any level of the stack 28 are in wafer form, partial wafer form, or singulated. For example, singulated die may be placed over die sites that are still a part of a wafer, and once the solder ball, underfill, and reflow processes have been completed, the wafer may be singulated. Regardless of the specific stacking technique used, the die stack 28 is supported by a substrate 30 that includes at least one contact pad 32 in electrical communication with a die's TSV 10, either directly as shown or through solder balls or some other connection medium. The substrate 30 also contains at least one electrically conductive trace 34 that redistributes electrical signals between the contact pad 32 and at least one electrical terminal 36 in another location on the substrate 30 (usually further out toward the perimeter of the substrate 30, and possibly on the other side as shown). That terminal 36 may be coupled to a solder ball known in the art as an outer lead bond (OLB) ball 38.

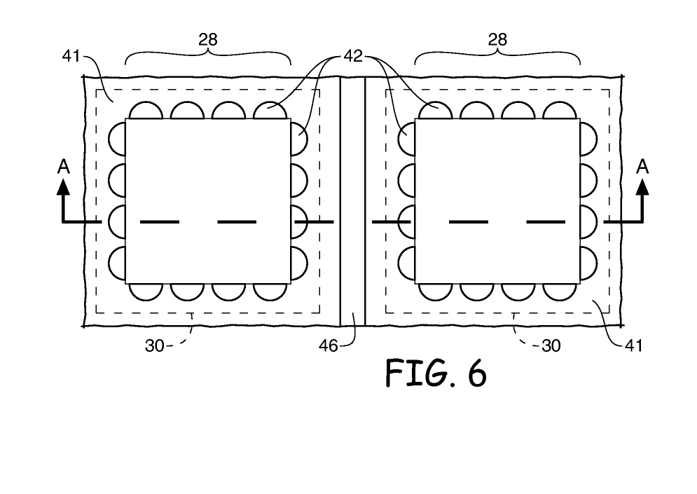

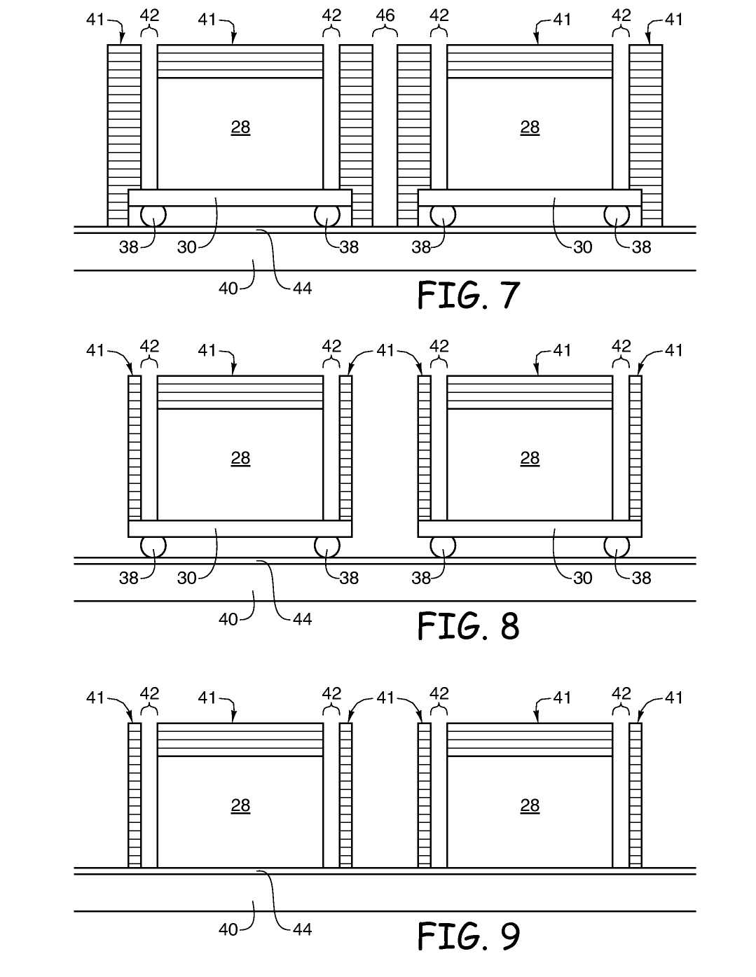

Once singulated, the die stack 28 and its substrate 30 may be placed on a carrier 40 (using an adhesive) along with other die stacks 28, as seen in FIG. 5. The stacks 28 are spaced apart sufficiently to perform the stereo lithography process illustrated in FIGS. 6 and 7. FIGS. 6 (top-down view) and 7 (cross-sectional side view along axis A) illustrate that a stereo lithography process may be used to add packaging 41 around at least the die stack 28, wherein the packaging 41 partially defines at least one channel 42 extending generally along the height of the die stack 28 (the die stack 28 also partially defines channel 42). The illustrated result may be achieved by lowering the carrier 40 with at least one die stack 28 into a tank of SI40 SL material to a depth such that at least the adhesive 44 is covered by the SI40 material. A laser may then be used to at least partially cure portions of the relevant cross-section for packaging 41. Next, the carrier may be further lowered into the tank, and the laser may be used to cure the relevant portions of the subsequent cross-section. At some point, a portion of the SI40 material may intersect the site for channel 42, and that portion may be left uncured. In addition, a region 46 between one die stack 28 and an adjacent die stack 28 may be left uncured to assist in separating a die stack 28/substrate 30/packaging 41 combination from its neighbors and from the adhesive 44. Uncured portions of the SI40 material may be removed from the die stack 28/substrate 30 before, during, or after that separation; and additional curing may be applied as needed. One of ordinary skill in the art would understand that channel 42 may branch and vary in diameter as may channel 20 discussed above.

The embodiments addressed above demonstrate to one of ordinary skill in the art that still other embodiments of the invention exist. For example, as seen in FIG. 8, the curing pattern for the stereo lithography process may be modified such that packaging 41 does not extend past the perimeter of substrate 30. In another example illustrated in FIG. 9, packaging 41 may be added around and above the die stack 28 using stereo lithography as described above, but that process may be performed before attaching the die stack 28 to the substrate 30.

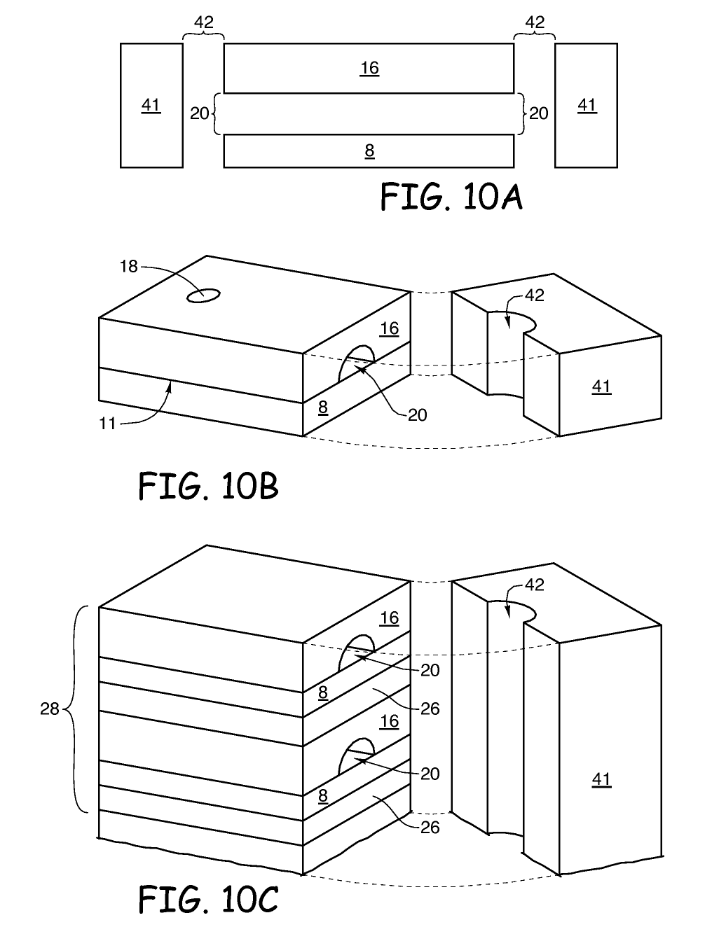

Other embodiments of the invention include those wherein a channel 20 over side 11 of a die 8 may be combined with a channel 42 along the perimeter of die 8. FIGS. 10A and B illustrate an embodiment wherein a die 8 has undergone a stereo lithography process such as one described above such that at least one channel 20 is defined by passivation 16 and side 11. Die 8 and passivation 16 may subsequently undergo another stereo lithography process such as one described above such that at least one channel 42 is defined by packaging 41 and the perimeter of die 8/passivation 16. In the illustrated embodiment, channel 20 and channel 42 meet. Die 8, along with its passivation 16 and packaging 41, may then be stacked with other die that have been processed similarly. Alternatively, as shown in FIG. 10C, die 8 may be stacked with other die after passivation 16 is added as described above, and packaging 41 may then be added to the stack 28 as described above.

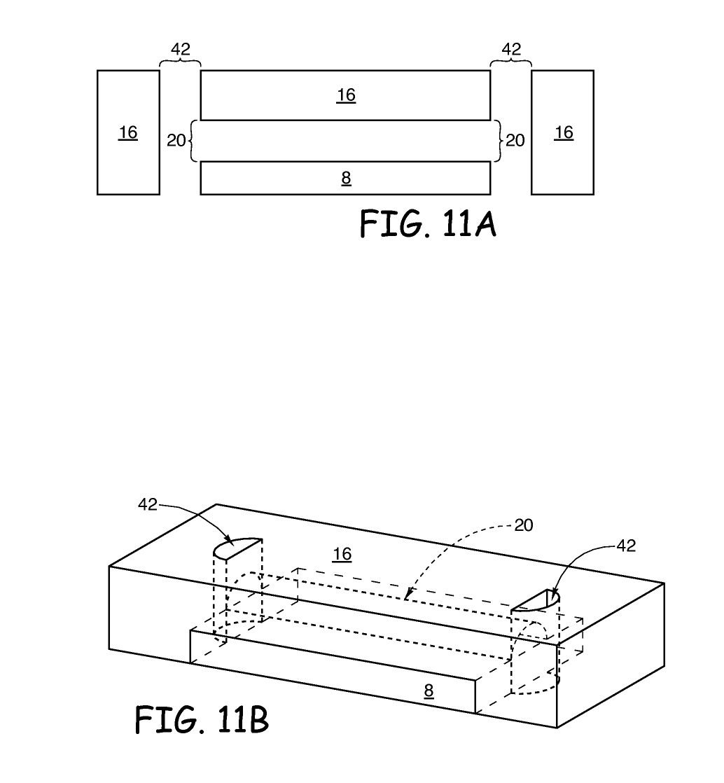

Still another alternative is illustrated in FIGS. 11A and B, wherein a die 8 has undergone a stereo lithography process similar to one described above but where passivation 16 extends beyond the perimeter of die 8, and passivation 16 and die 8 define both channels 20 and 42. Die 8 along with its passivation 16 may subsequently be stacked with other die that have been processed similarly.

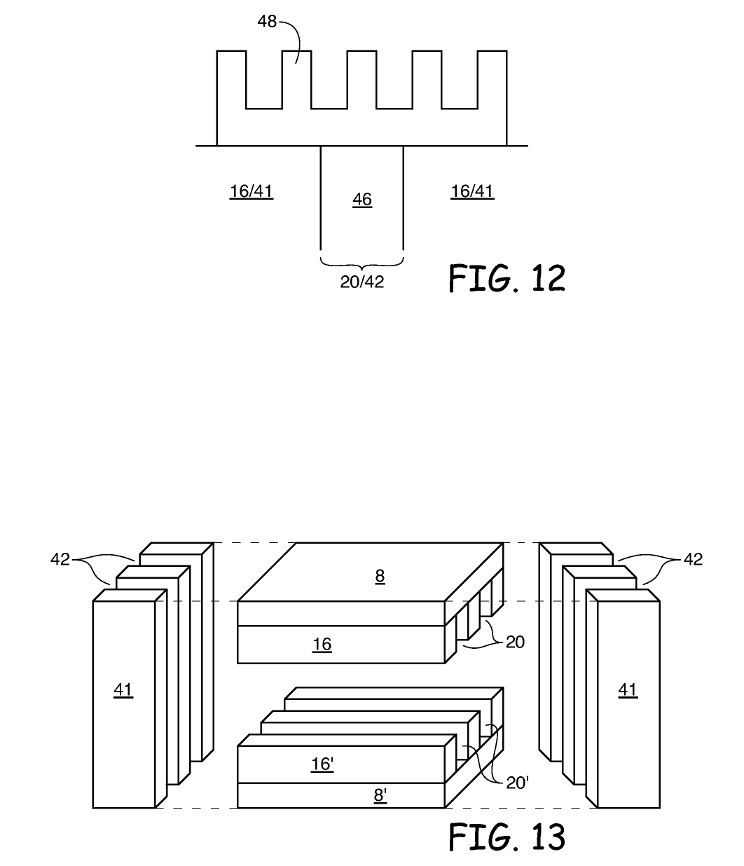

In at least one embodiment, channel 20 and/or 42 may address a package weight issue. Channel 20 and/or 42 may also provide flexibility or stress relief in at least one embodiment. In some embodiments, a material 46 may be added within channel 20 and/or 42. For example, a conductive solid, liquid, or non-ambient gas may be added for cooling. Adding the material 46 may be achieved by way of injection or some other manner of exposing the channel 20/42 to an environment containing the material 46. Accordingly, in some embodiments channel 20 and/or 42 may lead to a heat sink 48, as seen in FIG. 12. Furthermore, such a material 46 in channel 20 and/or 42 may additionally or alternatively serve as an electromagnetic shield or as an antenna.

One of ordinary skill in the art would also understand that die 8 need not include a TSV 10. Moreover, stereo lithography processes may be used to locate additional or alternative passivation 16 adjacent the side of the die 8 opposing side 11. In FIG. 13, for example, it is assumed that die 8 includes only one side with contact pads, deemed to be the “face” of the die, with the opposing side being deemed to be the “back.” Die 8 has passivation 16 on it's “back.” Die 8′, however, has passivation on its “face.” Further, if passivation concerns allow, channels 20 and 20′ may extend the full thickness of passivation 16, as also seen in FIG. 13. FIG. 13 further illustrates that, when die 8 and 8′ are stacked back-to-face, their channels 20 and 20′ align. (FIG. 13 could be understood to illustrate a face-to-back, face-to-face, or back-to-back stack of die as well.) In addition, at some point in the process (such as during or after adding passivation 16 and 16′) additional packaging 41 may be added to the perimeter of the die, and that packaging 41 may define channels 42 that also extend the full thickness of packaging 41. Accordingly, embodiments of the invention are not limited except as stated in the claims.

What is claimed is:

1. A semiconductor die package, comprising:
a material at most partially defining a channel; and
a semiconductor die coupled to the material and partially defining the channel.

2. The package in claim 1, wherein the material and die define a channel having at least one open end.

3. The package in claim 2, wherein the die comprises a side exposing at least one via, and the side partially defines the channel distal from the via.

4. The package in claim 2, wherein the die comprises a side having at least one contact pad, and the side partially defines the channel.

5. The package in claim 2, wherein the die comprises:
a first side exposing at least one via;
a second side parallel to the first side and having at least one contact pad; and
a third side perpendicular to the first side, wherein the third side partially defines the channel.

6. The package in claim 1,
wherein the die is a first die; and
the package further comprises:
a second semiconductor die partially defining a second channel,
additional material partially defining the second channel, coupled to the second die, and between the first and second die.

7. A lithography method, comprising:
partially submerging a semiconductor die in a material, wherein the die comprises:
a first side, and
a second side perpendicular to the first side and including an end of a via; and
curing the material at the first side, wherein the curing act defines a channel.

8. The method in claim 7, wherein the curing act defines a channel abutting the first side.

9. The method in claim 7, wherein the method further comprises:
further submerging the die; and
curing additional material.

10. The method in claim 9, wherein the act of curing additional material further defines the channel.

11. The method in claim 9, wherein:
curing the material at the first side defines a first channel;
further submerging the die comprises completely submerging the die;
curing additional material defines a second channel perpendicular to the first channel.

12. The method in claim 9, wherein,
further submerging the die comprises:
completely submerging a first die, and
partially submerging a second die over the first die; and
curing additional material further defines the channel.

13. A passivator for a die comprising:
an insulator on a side of the die and at least partially defining a channel extending parallel to the side,
wherein the channel avoids any conductor on the side.

14. The passivator in claim 13, wherein the insulator defines a channel having different diameters.

15. The passivator in claim 13, wherein the insulator defines a branching channel.

16. A method of processing at least one wafer of die, comprising:
forming a stack of die;
singulating die from at least one wafer; and
adding insulation to at most a portion of a side of the stack using stereo lithography.

17. The method in claim 16, wherein:
the act of forming a stack of die comprises stacking a plurality of wafers; and
the act of singulating comprises dicing through the plurality of wafers.

18. The method in claim 16, wherein the act of forming a stack of die comprises stacking at least one singulated die over a die site of a wafer.

19. The method in claim 16, further comprising placing at least one stack over a wafer-scale carrier.

20. The method in claim 19, further comprising placing at least one stack onto a substrate.

21. The method in claim 20, wherein adding insulation comprises forming a gap extending down to the substrate.

22. The method in claim 21 wherein adding insulation further comprises forming another gap located between two stacks and extending down to the carrier.

23. The method in claim 22 wherein adding insulation further comprises forming another gap extending down to an adhesive of the carrier.

24. A method of processing a wafer including a plurality of die sites, comprising:
adding material on the wafer;
curing a first portion of the material in a region around at least one channel site over each of at least two adjacent die sites; and
refraining from curing a second portion of the material coinciding with the channel site of at least two adjacent die sites.

25. The method in claim 24, further comprising refraining from curing a third portion of the material between adjacent die sites.

26. The method in claim 25, wherein:
the act of adding material comprises adding a first amount of material on the wafer; and
the method further comprises:
adding a second amount of material on the first amount, and
curing the second amount of material over at least one channel site of at least two adjacent die sites.

27. A method of thermally regulating a semiconductor die, comprising:
exposing the die to a thermally conductive material; and
limiting die exposure of the material to at most a semiconductive portion of the die.

28. Packaging for a semiconductor die, comprising an electrically insulative material at least partially around the die, wherein the material defines an opening at a surface of the die and closes the opening above the surface.

29. The packaging of claim 28, further comprising a conductor in the opening, wherein the conductor consists of a selection of a solid, a liquid, a gas, and combinations thereof.

30. The packaging of claim 29, further comprising a heat sink coupled to the opening.
